(19) United States
(12) Patent Application Publication
(10) Pub. No.: US 2014/0060904 A1
(43) Pub. Date: Mar. 6, 2014

(54) PRINTED WIRING BOARD AND METHOD FOR MANUFACTURING PRINTED WIRING BOARD

(71) Applicant: IBIDEN CO., LTD., Ogaki-shi (JP)

(72) Inventor: Kazuki KAJIHARA, Ogaki-shi (JP)

(73) Assignee: IBIDEN CO., LTD., Ogaki-shi (JP)

(21) Appl. No.: 14/015,167

(22) Filed: Aug. 30, 2013

Related U.S. Application Data
(60) Provisional application No. 61/694,983, filed on Aug. 30, 2012.

(51) Int. Cl. H05K 1/02; H05K 3/10

(52) U.S. Cl. CPC H05K 1/0298; H05K 3/10
USPC 174/257; 228/165; 174/261

(57) ABSTRACT

A printed wiring board has an interlayer insulation layer, a conductive pattern formed on the interlayer insulation layer, a solder-resist layer formed on the interlayer insulation layer and the conductive pattern and having an opening portion exposing a portion of the conductive pattern and a portion of the interlayer insulation layer around the portion of the conductive pattern, a metal layer formed in the opening portion of the solder-resist layer such that the metal layer is covering the portion of the conductive pattern and the portion of the interlayer insulation layer exposed through the opening portion of the solder-resist layer, and a bump structure formed in the opening portion of the solder-resist layer such that the bump structure is formed on the metal layer in the opening portion of the solder-resist layer.

### CROSS-REFERENCE TO RELATED APPLICATIONS

The present application is based upon and claims the benefit of priority from U.S. Application No. 61/694,983, filed Aug. 30, 2012, the entire contents of which are incorporated herein by reference.

### BACKGROUND OF THE INVENTION

1. Field of the Invention

The present invention relates to a printed wiring board having buildup layers formed by alternately laminating interlayer insulation layers and conductive patterns, and to a method for manufacturing such a printed wiring board.

2. Description of Background Art

Japanese Laid-Open Patent Publication No. 2010-103435 describes a structure where lands (pads) are not formed, allowing space for positioning conductive patterns to be enlarged so that the number of conductive patterns is increased. The entire contents of this publication are incorporated herein by reference.

### SUMMARY OF THE INVENTION

According to one aspect of the present invention, a printed wiring board has an interlayer insulation layer, a conductive pattern formed on the interlayer insulation layer, a solder-resist layer formed on the interlayer insulation layer and the conductive pattern and having an opening portion exposing a portion of the conductive pattern and a portion of the interlayer insulation layer around the portion of the conductive pattern, a metal layer formed in the opening portion of the solder-resist layer such that the metal layer is covering the portion of the conductive pattern and the portion of the interlayer insulation layer exposed through the opening portion of the solder-resist layer, and a bump structure formed in the opening portion of the solder-resist layer such that the bump structure is formed on the metal layer in the opening portion of the solder-resist layer.

According to another aspect of the present invention, a method for manufacturing a printed wiring board includes forming a conductive pattern on an interlayer insulation layer, forming a solder-resist layer on the interlayer insulation layer and the conductive pattern, forming an opening portion in the solder-resist layer such that the opening portion of the solder-resist layer exposes a portion of the conductive pattern and a portion of the interlayer insulation layer around the portion of the conductive pattern, forming a metal layer in the opening portion of the solder-resist layer such that the metal layer covers the portion of the conductive pattern and the portion of the interlayer insulation layer exposed through the opening portion of the solder-resist layer, and forming a bump structure in the opening portion of the solder-resist layer such that the bump structure is formed on the metal layer in the opening portion of the solder-resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-1(C) are views showing steps for manufacturing a printed wiring board according to a first embodiment of the present invention;

FIGS. 2(A)-2(D) are views showing steps for manufacturing a printed wiring board according to the first embodiment;

FIGS. 3(A)-3(C) are views showing steps for manufacturing a printed wiring board according to the first embodiment;

FIGS. 4(A)-4(C) are views showing steps for manufacturing a printed wiring board according to the first embodiment;

FIGS. 5(A)-5(C) are views showing steps for manufacturing a printed wiring board according to the first embodiment;

FIG. 6 is a cross-sectional view of a printed wiring board according to the first embodiment;

FIGS. 7(A)-7(B) are plan views of outermost conductive patterns;

FIG. 8(A) is a cross-sectional view showing the positional relationship of a pad portion and an opening; FIG. 8(B) is a plan view; FIG. 8(C) is a view illustrating an allowable margin of error between a pad portion and an opening;

FIG. 9(A) is an enlarged view of circle (Ca) in FIG. 5(A); FIG. 9(B) is an enlarged view of circle (Cb) in FIG. 5(B); FIG. 9(C) is an enlarged view of circle (Cc) in FIG. 6;

FIG. 10 is a microscopic photograph of a bump;

FIGS. 11(A)-11(B) are plan views of conductive patterns of a printed wiring board according to a modified example of the first embodiment; and

FIGS. 12(A)-12(C) are views showing steps for manufacturing a bump of a printed wiring board according to a second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

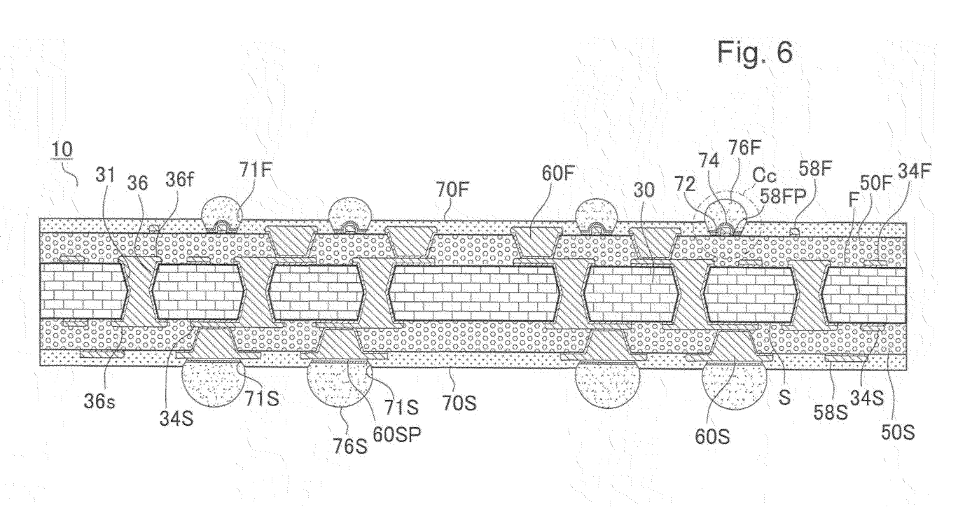

FIG. 6 shows a structure of printed wiring board 10 according to a first embodiment of the present invention. Printed wiring board 10 includes core substrate 30 which has first surface (F) (upper surface: the side where a semiconductor element is to be mounted) and second surface (S) (lower surface: the side where a motherboard is to be mounted). First conductive pattern (34F) is formed on first surface (F) of core substrate 30, and second conductive pattern (34S) is formed on second surface (S). Through-hole conductor 36 is formed in core substrate 30, and first conductive pattern (34F) and second conductive pattern (34S) are connected by through-hole conductor 36. Of the end portions of through-hole conductor 36, first conductor land (36f) is formed on the first-surface (F) side, and second conductor land (36s) is formed on the second-surface (S) side. First interlayer insulation layer (50F) is formed to cover first surface (F) of core substrate 30 and first conductive pattern (34F). Conductive pattern (58F) is formed on first interlayer insulation layer (50F), and conductive pattern (58F) and first conductive pattern (34F) are connected by via hole (60F). Solder-resist layer (70F) is formed to cover first interlayer insulation layer (50F) and conductive pattern (58F). Solder-resist layer (70F) has opening (71F). Then, solder bump (76F) is formed in opening (71F). Also, second interlayer insulation layer (50S) is formed to cover second surface (S) of core substrate 30 and second conductive pattern (34S). Conductive pattern (58S) is formed on second interlayer insulation layer (50S), and conductive pattern (58S) and second conductive pattern (34S) are connected by via hole (60S). Solder-resist layer (70S) is formed to cover second interlayer insulation layer (50S) and conductive pattern (58S). Solder-resist layer (70S) has opening (71S). Then, solder bump (76S) is formed in opening (71S).

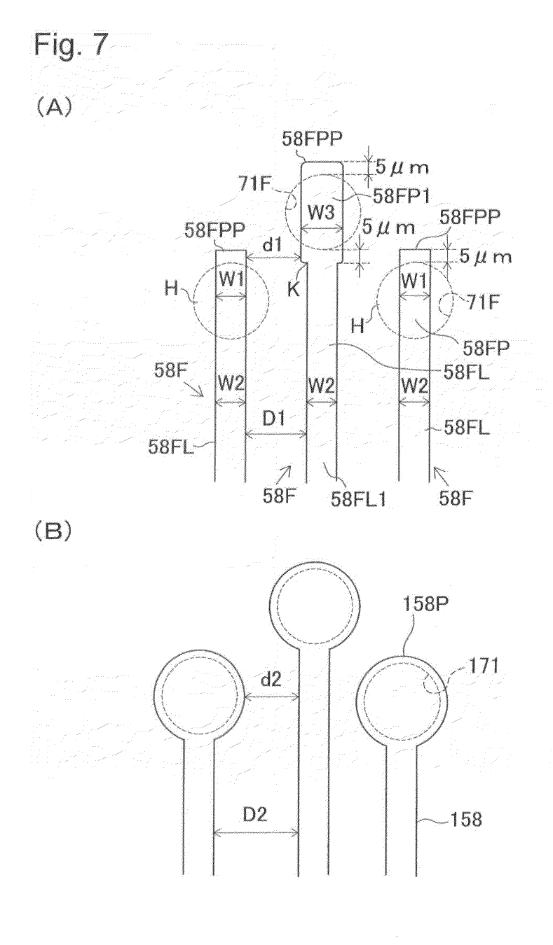

FIG. 7(A) shows plan views of conductive patterns (58F) formed on first interlayer insulation layer (50F). The chain lines in FIG. 7(A) show openings (71F) of solder-resist layer (70F). In a conductive pattern (58F), a portion exposed through opening (71F) of solder-resist layer (70F) works as pad portion (58FP). Solder bump (76F) for connection with a semiconductor element is formed on pad portion (58FP). Moreover, conductive pattern (58F) has wiring portion (58FL) extending from pad portion (58FP). In the first embodiment, the diameter of opening (71F) is approximately 50 μm, and width (W1) of pad portion (58FP) is approximately 15 μm, while width (W1) of pad portion (58FP) is set substantially the same as width (W2) of wiring portion (58FL). Here, among pad portions (58FP), pad portion (58FP1) has width (W3) of approximately 30 μm. Pad portions (58FP) are shaped to be substantially rectangular in a planar view. End portion (58FPP) of conductive pattern (58F) is covered by solder-resist layer (70F). Accordingly, the adhesiveness of conductive pattern (58F) with first interlayer insulation layer (50F) is secured. In some of conductive patterns (58F), boundary portion (K) between pad portion (58FP1) and wiring portion (58FL1) is covered by solder-resist layer (70F). Accordingly, boundary portion (K) is prevented from touching solder bump (76F), and cracking originating at boundary portion (K) and spreading inside bump (76F) is suppressed.

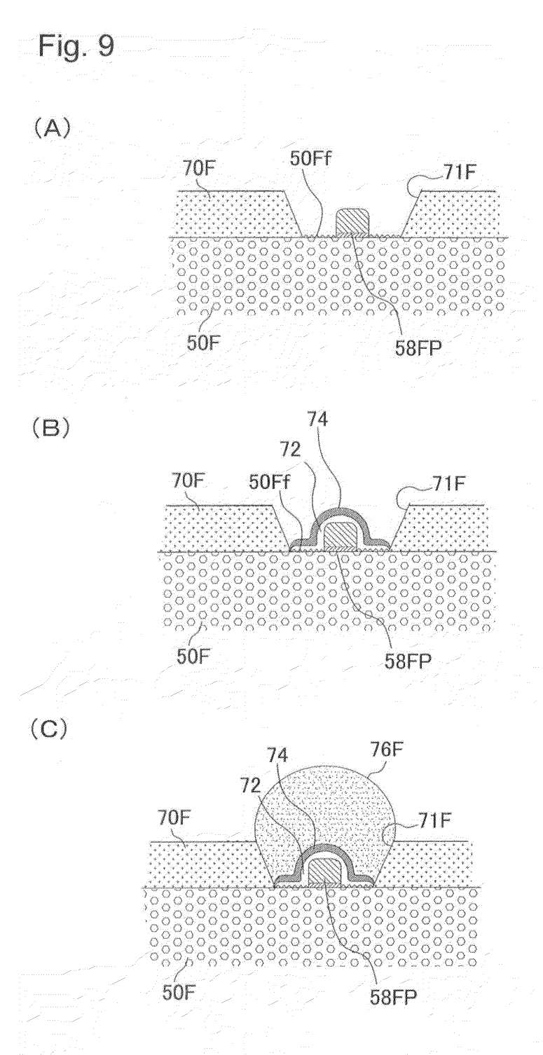

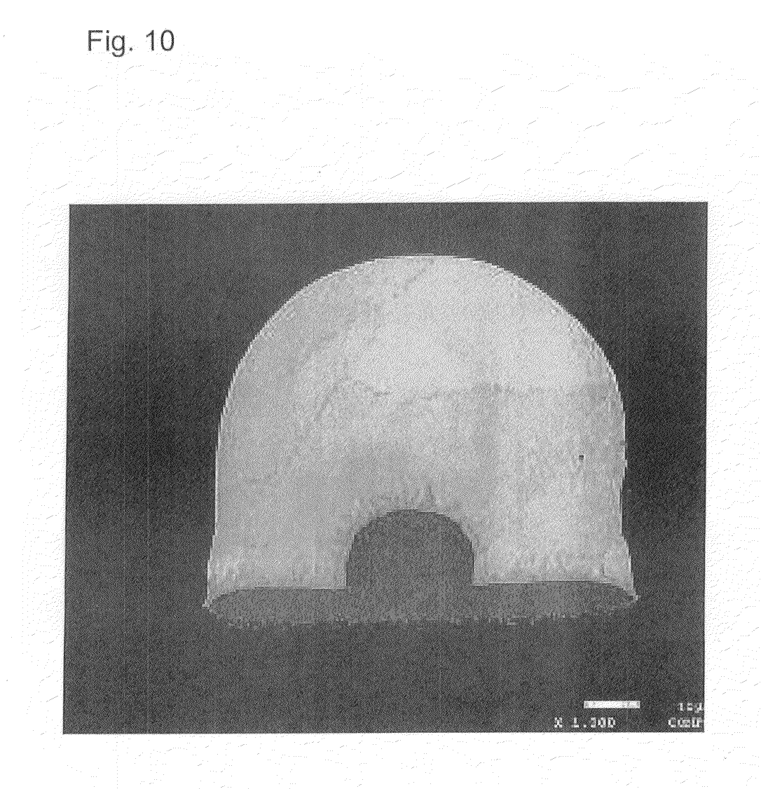

Furthermore, surface (H) of first interlayer insulation layer (50F) positioned around pad portion (58FP) is exposed through opening (71F) of solder-resist layer (70F). Here, FIG. 9(C) is an enlarged view of a portion in circle (Cc) of FIG. 6 exposed through opening (71F) of solder-resist layer (70F) on the first-surface (F) side, and FIG. 10 is a microscopic photograph of that portion. As described above, interlayer insulation layer (50F) and pad portion (58FP) are exposed through opening (71F) of solder-resist layer (70F). The surface of interlayer insulation layer (50F) exposed through opening (71F) is roughened. Corners of pad portion (58FP) are formed in substantially an arc shape in a cross-sectional view. Therefore, when thermal history is added to a printed wiring board, stress exerted on corners of pad portion (58FP) is mitigated. As a result, cracking originating at corners of pad portion (58FP) and spreading inside solder bump (76F) is thought to be suppressed.

Metal layer 80 made up of nickel-plated layer 72 and gold-plated layer 74 is formed on interlayer insulation layer (50F) and on pad portion (58FP) which are exposed through opening (71F). The surface of metal layer 80 on pad portion (58FP) is curved with a substantially semicircular shape in a cross-sectional view. Also, metal layer 80 is formed in such a way that its thickness is thinner at corners of pad portion (58FP) while its relative thickness increases on the upper surface of pad portion (58FP).

Solder bump (76F) formed on metal layer 80 is filled in opening (71F) without leaving any gap, and makes contact with the entire side surface of opening (71F).

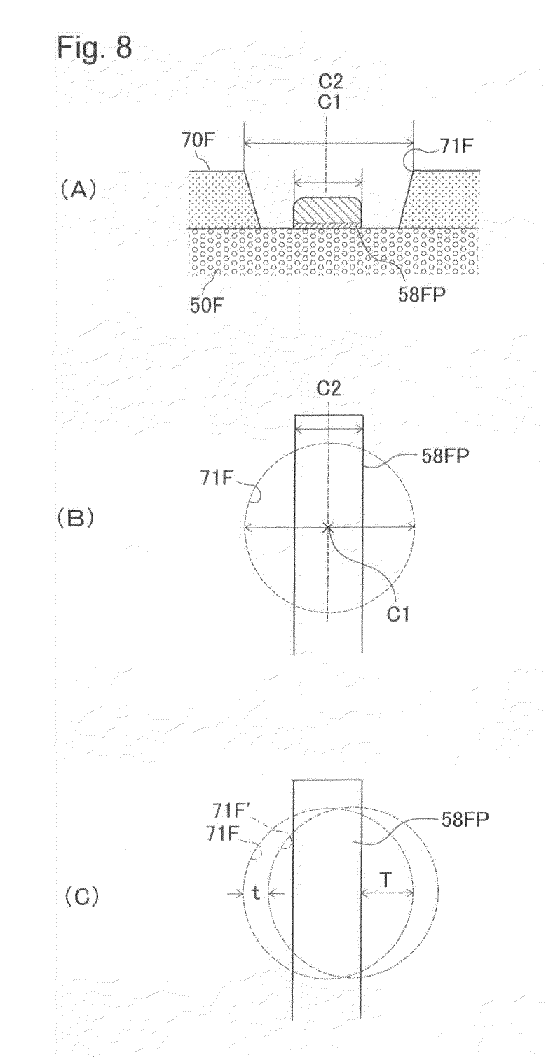

FIG. 8(A) is a cross-sectional view showing the positional relationship of pad portion (58FP) and opening (71F), and FIG. 8(B) is a plan view. Their positions are set so that center (C1) of opening (71F) intersects with virtual line (C2) which passes through the center in a lateral direction of pad portion (58FP) and extends in a longitudinal direction. In setting so, a left portion of bump (76F) and a right portion of bump (76F) from center (C2) of a pad portion in an axis direction become symmetrical. Accordingly, stress is not concentrated locally, and the connection reliability of bump (76F) is easier to secure.

FIG. 8(C) shows an allowable margin of error between pad portion (58FP) and opening (71F). Opening (71F) shows an opening without errors. Distance (T) ((50−15)÷2=17.5 μm) is formed between opening (71F) and a side wall of pad portion (58FP). (71F′) shows an opening with maximum allowable error (t). In the first embodiment, maximum allowable margin of error (t) is set to be smaller than distance (T).

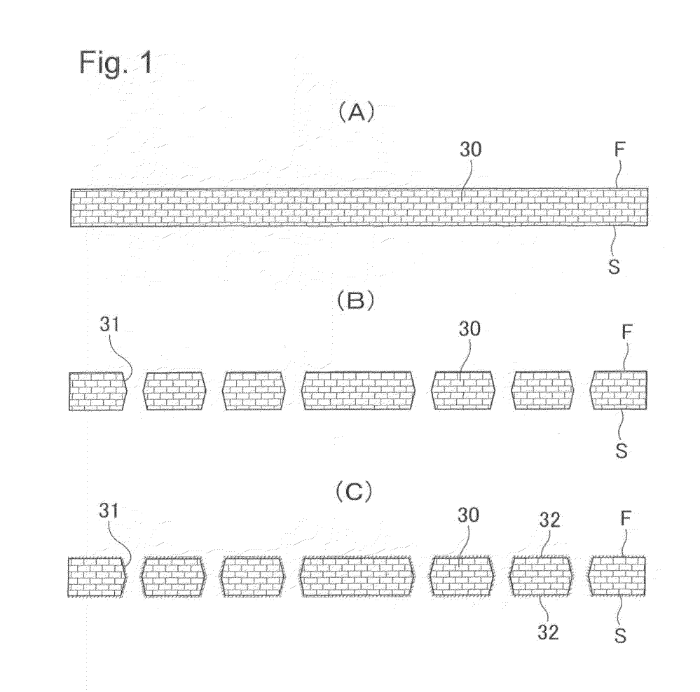

In a printed wiring board of the first embodiment, circular pad (158P) of conventional art shown in FIG. 7(B) is not used, but a portion that works as a pad (pad portion (58FP): width (w1)) and the rest of wiring line (58FL) (width (W1)) are formed to have substantially the same width. Here, in the conventional art, space (D2) between conductive patterns increases inevitably to maintain insulation distance (d2) (d2≈d1) between circular pad (158P) and conductive pattern 158 (D2>D1). By contrast, in the first embodiment, pad portion (58FPP) is in a rectangular shape, and its width is substantially the same as the width of the wiring portion as shown in FIG. 7(A). Thus, when distance (d1) between pad portions (58FPP) is the same as (d2) above, space (D1) between conductive patterns becomes smaller than (D2) above. Namely, in the first embodiment, the number of conductive patterns per unit area can be increased compared with the conventional art, allowing a high-density routing of conductive patterns. Usually, in a printed wiring board to mount a semiconductor element, intervals of conductive patterns increase by gradually fanning out from the outermost layer directly under the semiconductor element (on the uppermost interlayer insulation layer) toward the outermost layer on the motherboard side (on the lowermost interlayer insulation layer) so that fine electrodes of a semiconductor element are connected to the electrodes on the motherboard side. Therefore, the density of uppermost conductive patterns is the highest, further increasing the density of the conductive patterns on the uppermost layer where highest density is desired. In addition, by setting the diameter of opening (71F) of solder-resist layer (70F) to be greater than the width of conductive pattern (58F), if accuracy errors with respect to a conductive pattern occur during the formation of opening (71F), it is easier to expose conductive pattern (58F) (pad portion). As a result, it is easier to secure the connection of solder bump (76F) with conductive pattern (58F) (pad portion), and sufficient connection reliability is achieved between them. Furthermore, metal layer 80 is formed on a conductive pattern and on the interlayer insulation layer which are exposed through opening (71F) of solder-resist layer (70F), and solder bump (76F) is formed on metal layer 80. Thus, in opening (71F) of solder-resist layer (70F), a solder bump is formed on a conductive pattern as well as on the interlayer insulation layer surrounding the conductive pattern. As a result, the connection reliability of a semiconductor element is secured, making it easier to form bumps which can mitigate stress during mounting procedures. A method for manufacturing printed wiring board 10 in FIG. 6 is shown in FIGS. 1˜6.

(1) Insulative substrate 30 is starting material, which is 0.2 mm thick and made by impregnating core material such as glass cloth with epoxy resin or BT (bismaleimide triazine) resin (FIG. 1(A)). Penetrating holes 31 for through-hole conductors are formed using a laser from the upper-surface (first-surface (F)) side and the lower-surface (second-surface (S)) side (FIG. 1(B)).

(2) A palladium catalyst (made by Atotech) is applied on the upper surface of insulative substrate 30, and electroless copper plating is performed to form 0.6 μm-thick electroless copper-plated film (seed layer) 32 on the upper surface of the substrate and on side walls of penetrating holes 31 for through-hole conductors (FIG. 1(C)).

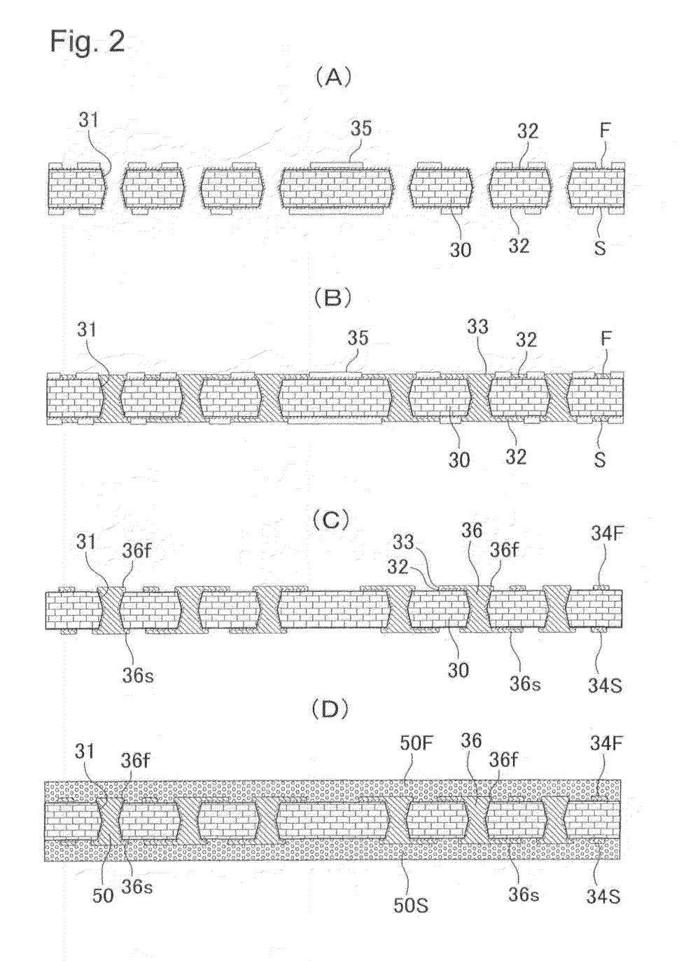

(3) Then, a commercially available dry film is laminated on both surfaces of insulative substrate 30, and plating resists 35 are formed through exposure and development (FIG. 2(A)).

(4) Electrolytic plating is performed to form electrolytic copper-plated film 33 in penetrating holes 31 and on portions of substrate 30 where plating resists 35 are not formed (FIG. 2(B)).

(5) Then, after plating resists 35 are removed using an amine solution, electroless plated film 32 where the plating resists were formed are dissolved and removed by an etching solution mainly containing copper (II) chloride to form first conductive patterns (34F) and second conductive patterns (34S) including first conductor land (36f) and second conductor land (36s) (FIG. 2(C)).

(6) Resin film for interlayer insulation layers (brand name ABF-45SH, made by Ajinomoto), which does not contain core material and is a little smaller than the substrate, is placed on the upper surface (first surface) and lower surface (second surface) of substrate 30, preliminarily pressed and cut to size, and then laminated using a vacuum laminator. Accordingly, first interlayer insulation layer (50F) and second interlayer insulation layer (50S) are formed (FIG. 2(D)).

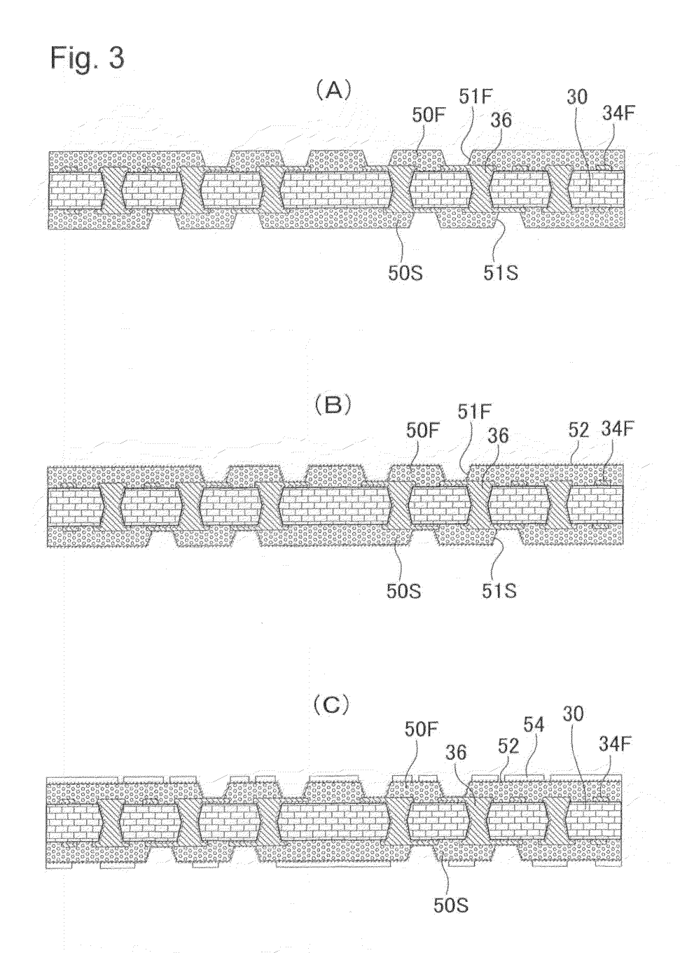

(7) Next, using a CO2 gas laser, via-hole openings (51F, 51S) are formed in interlayer insulation layers (50F, 50S) (FIG. 3(A)).

(8) The substrate with via-hole openings (51F, 51S) is immersed in an 80° C. solution containing 60 g/L of permanganic acid for 10 minutes to remove particles existing on upper surfaces of interlayer insulation layers (50F, 50S). Accordingly, the upper surfaces of interlayer insulation layers (50F, 50S) including the inner walls of via-hole openings 51 are roughened (not shown in the drawings).

(9) Next, after the above treatments, the substrate is immersed in a neutralizer (made by Shipley) and is washed with water. Moreover, by applying a palladium catalyst on the roughened surfaces of the substrate, catalyst nuclei are attached on the upper surfaces of interlayer insulation layers and on the inner-wall surfaces of via-hole openings.

(10) Next, the substrate with attached catalyst is immersed in an electroless copper plating solution (Thru-cup PEA) made by C. Uyemura & Co., Ltd. so that electroless copper-plated film with a thickness of 0.3˜3.0 μm is formed on the entire roughened surface. Accordingly, a substrate is obtained having electroless copper-plated film 52 formed on the upper surfaces of first interlayer insulation layer (50F) and second interlayer insulation layer (50S) including the inner-wall surfaces of via-hole openings (51F, 51S) (FIG. 3(B)).

(11) A commercially available photosensitive dry film is laminated on the substrate where electroless copper-plated films 52 are formed, and masks are placed and exposure/development treatments are conducted to form plating resists 54 (FIG. 3(C)).

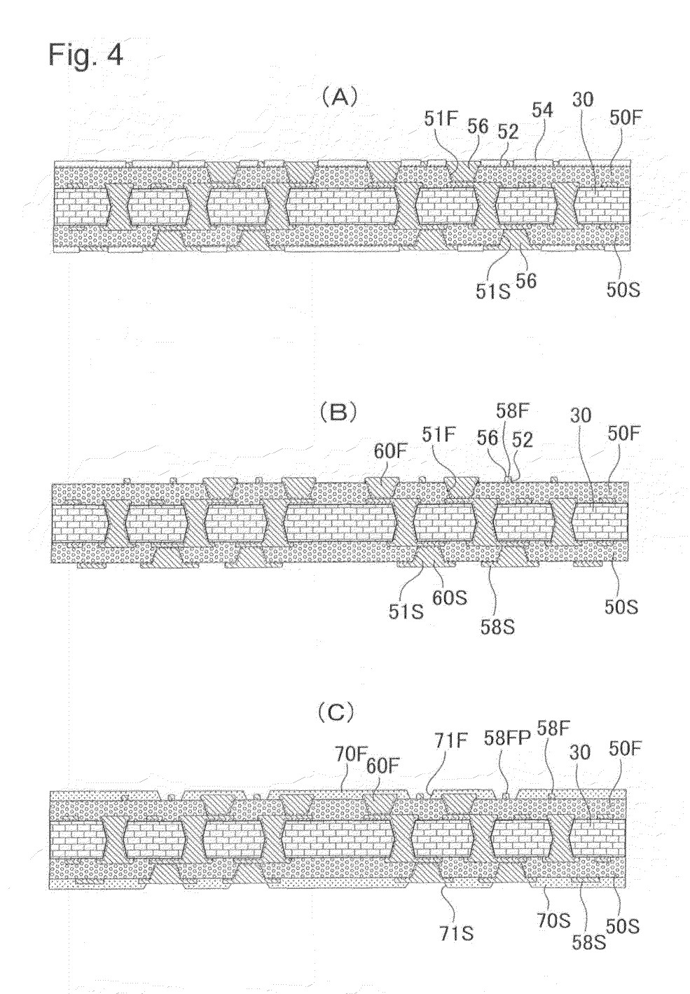

(12) The substrate is washed with 50° C. water to cleanse and degrease. After being washed with water, the substrate is further cleansed by sulfuric acid. Then, electrolytic plating is performed to form 15 μm-thick electrolytic copper-plated films 56 in portions where plating resists 54 are not formed (FIG. 4(A)).

(13) Moreover, after plating resists 54 are removed by a 5% KOH solution, electroless plated films under the plating resists are etched away using a mixed solution of sulfuric acid and hydrogen peroxide to form conductive patterns (58F, 58S) and via holes (60F, 60S) (FIG. 4(B)). Then, upper surfaces of conductive patterns (58F, 58S) and via holes (60F, 60S) are roughened.

(14) Next, on both surfaces of the multilayer wiring board, a commercially available solder-resist composition is applied to be 20 μm thick and dried. Then, a 5-mm thick photomask with a pattern of solder-resist opening portions is adhered to solder-resist layers, exposed to UV rays and developed using a DMTG solution. Accordingly, openings (71F) with a smaller diameter are formed on the upper-surface side, and openings (71S) with a larger diameter are formed on the lower-surface side (FIG. 4(C)). Conductive patterns (58F) exposed through openings (71F) form pad portions (58FP). Moreover, the solder-resist layers are cured by thermal treatments, and solder-resist layers (70F, 70S) having openings and a thickness of 15˜25 μm are formed.

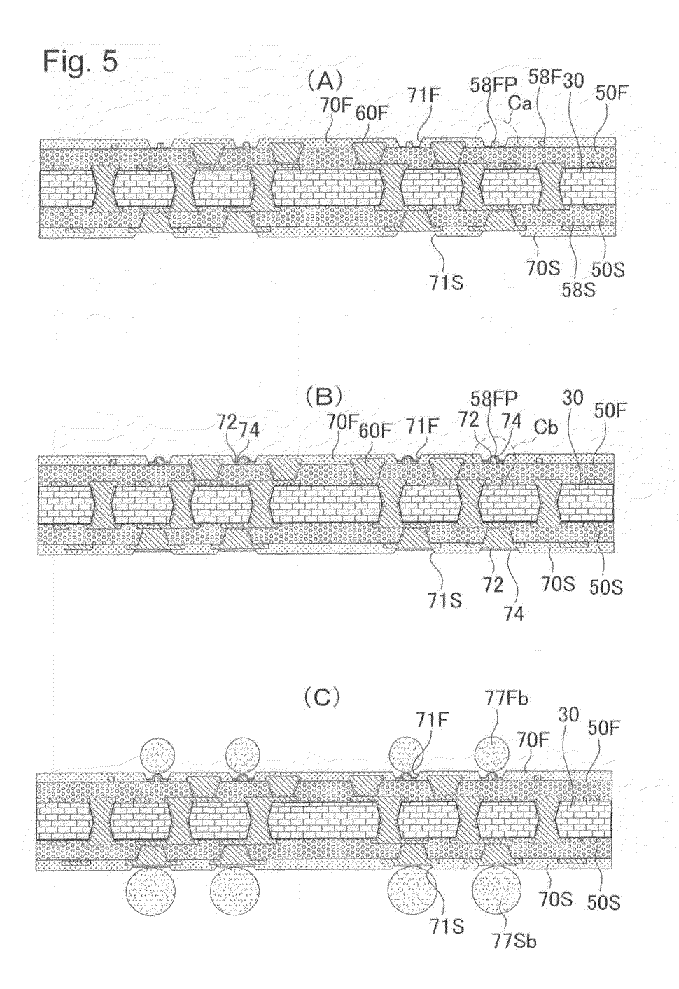

(15) Oxygen plasma treatments are conducted in openings (71F) of solder-resist layer (70F), and the surface of interlayer insulation layer (50F) exposed in the openings is roughened (FIG. 5(A)). FIG. 9(A) is an enlarged view of a portion in circle (Ca) in FIG. 5(A).

(16) Next, the substrate with solder-resist layers (70F, 70S) is immersed in an electroless nickel plating solution to form 5 μm-thick nickel-plated layer 72 in opening portions (71F, 71S). Then, the substrate is further immersed in an electroless gold plating solution to form 0.03 μm-thick gold-plated layer 74 on nickel-plated layer 72 (FIG. 5(B)). During that time, since a palladium catalyst remains on the entire portion exposed through opening portion (71F), a metal layer made of nickel-plated layer 72 and gold-plated layer 74 is formed on the entire portion exposed through opening portion (71F). FIG. 9(B) is an enlarged view of a portion in circle (Cb) in FIG. 5(B)). Instead of nickel-gold layers, triple layers made of nickel-palladium-gold layers, single layers made of tin or noble metals (such as gold, silver, palladium or platinum) may also be formed. As described above, the surface of metal layer 80 is curved with its semicircular cross-sectional shape on pad portion (58FP). In addition, the surface of gold-plated layer 74 is curved with a smaller thickness at end portions of pad portion (58FP).

(17) After flux (not shown in the drawings) is applied in openings (71F, 71S), solder balls (77Fb) are loaded on openings (71F) of upper solder-resist layer (70F), and solder balls (77Sb) are loaded in openings (71S) of lower solder-resist layer (70S) (FIG. 5(C)). Next, a reflow is conducted to form solder bumps (76F) on the upper surface and solder bumps (76S) on the lower surface (FIG. 6). During the reflow process of solder balls (77Fb), due to the high solderability of gold-plated layer 74 above, solder bumps (76F) formed on gold-plated layer 74 are filled in openings (71F) without leaving space, and touch all the side surfaces of openings (71F).

A semiconductor element is mounted on printed wiring board 10, and a reflow is conducted so that pad portions of a printed wiring board and electrodes of the semiconductor element are connected through solder bumps (76F) (not shown in the drawings).

In the method for manufacturing a printed wiring board according to the first embodiment, after solder-resist layer (70F) is formed, the surface of interlayer insulation layer (50F) exposed through openings (71F) is roughened. Then, a metal layer is formed on the roughened surface of the interlayer insulation layer, and bumps are formed on the metal layer. Accordingly, the connection reliability of bumps to portions (interlayer insulation layer) exposed through openings (71F) is enhanced.

### First Modified Example of the First Embodiment

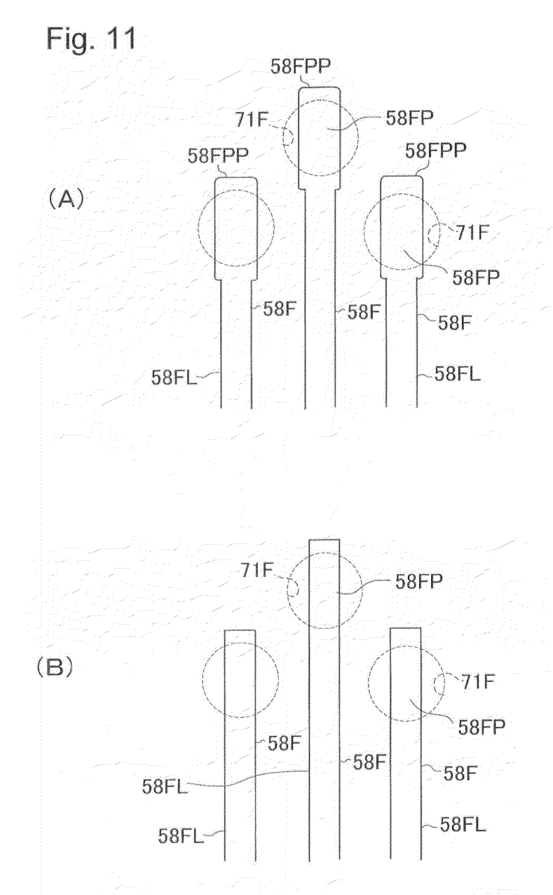

FIG. 11(A) is a plan view of conductive patterns (58F) of a printed wiring board according to a first modified example of the first embodiment. In the first modified example of the first embodiment, pad portion (58FP) is formed in rectangular pad portion (58FPP). In the first modified example of the first embodiment, since the width of pad portion (58FP) is wider, connection reliability is enhanced between pad portion (58FP) and a bump.

### Second Modified Example of the First Embodiment

FIG. 11(B) is a plan view of conductive patterns (58F) of a printed wiring board according to a second modified example of the first embodiment. Rectangular pad portions are not formed in the second modified example of the first embodiment. The density of conductive patterns is further enhanced in the second modified example of the first embodiment.

### Second Embodiment

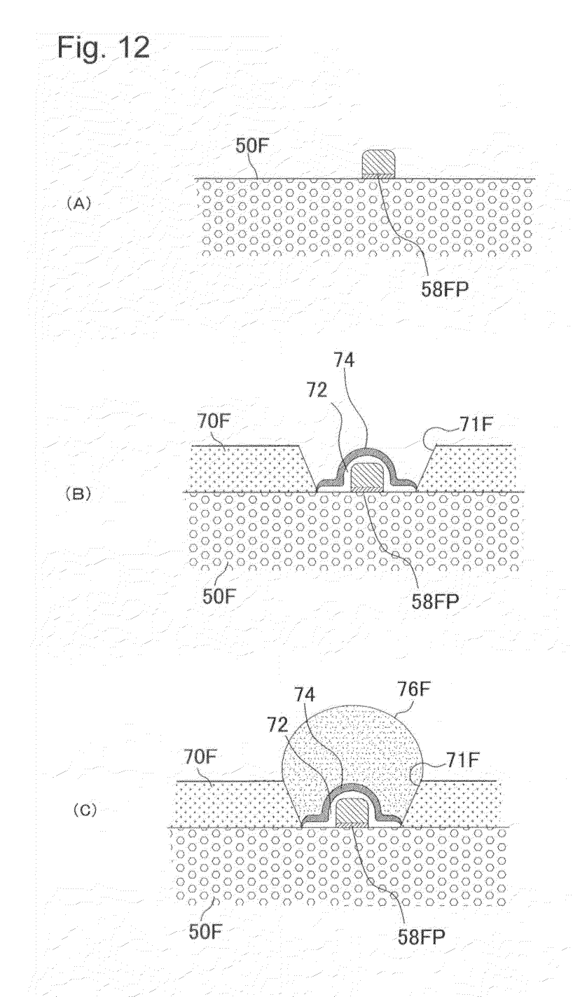

FIG. 12 shows a method for manufacturing a printed wiring board according to a second embodiment. When the electroless plated film under the plating resist is removed to form conductive patterns (58F) in the first embodiment described above with reference to FIG. 4(B), the palladium catalyst applied as catalyst nuclei for electroless plating is left sparsely on interlayer insulation layer (50F) at a level not to cause short circuiting (FIG. 12(A)). Then, because of the palladium catalyst, nickel-plated layer 72 and gold-plated layer 74 are formed on interlayer insulation layer (50F) exposed in openings (71F) of solder-resist layer (70F) (FIG. 12(B)). After that, bumps (76F) are formed in openings (71F) the same as in the first embodiment (FIG. 12(C)).

In the method for manufacturing a printed wiring board according to the second embodiment, since a palladium catalyst is left on interlayer insulation layer (50F) when forming conductive pattern (58F), a metal layer (nickel-plated film 72 and gold-plated film 74) is formed using the palladium catalyst through plating on the surface of the interlayer insulation layer exposed in opening (71F) of the solder-resist layer. Namely, bump (76F) is formed on the entire portion exposed through opening (71F) of the solder-resist layer, and the same effects as in the above first embodiment are achieved.

According to an embodiment of the present invention, a printed wiring board has an interlayer insulation layer, a conductive pattern formed on the interlayer insulation layer, and a solder-resist layer having an opening that exposes at least part of the conductive pattern and the interlayer insulation layer positioned around the conductive pattern. In such a printed wiring board, a metal layer is formed on the conductive pattern and on the interlayer insulation layer which are exposed through the opening, and a bump is formed on the metal layer in the opening.

In a printed wiring board according to an embodiment of the present invention, at least part of a conductive pattern and the interlayer insulation layer positioned around the conductive pattern are exposed through an opening of the solder-resist layer. Namely, the width of a conductive pattern (pad) is set smaller than the diameter of an opening of the solder-resist layer. Accordingly, compared with a case where the diameter of an opening of a solder-resist layer is smaller than the pad diameter, the region a pad occupies decreases, allowing high-density routing of conductive patterns. Furthermore, a metal layer is formed on a conductive pattern and on the interlayer insulation layer which are exposed through an opening of the solder-resist layer, and a bump is formed on the metal layer. Thus, a bump is formed on a conductive pattern and also on its surrounding interlayer insulation layer in the opening of the solder-resist layer. As a result, connection reliability of a semiconductor element is enhanced while forming a bump which can mitigate stress exerted during a mounting process.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an interlayer insulation layer;
a conductive pattern formed on the interlayer insulation layer;
a solder-resist layer formed on the interlayer insulation layer and the conductive pattern and having an opening portion exposing a portion of the conductive pattern and a portion of the interlayer insulation layer around the portion of the conductive pattern;
a metal layer formed in the opening portion of the solder-resist layer such that the metal layer is covering the portion of the conductive pattern and the portion of the interlayer insulation layer exposed through the opening portion of the solder-resist layer; and
a bump structure formed in the opening portion of the solder-resist layer such that the bump structure is formed on the metal layer in the opening portion of the solder-resist layer.

2. The printed wiring board according to claim 1, wherein the metal layer is formed in the opening portion of the solder-resist layer such that the metal layer is covering an entire portion exposed through the opening portion of the solder-resist layer.

3. The printed wiring board according to claim 1, wherein the bump structure is formed in the opening portion of the solder-resist layer such that the bump structure is in contact with an entire side wall of the opening portion of the solder-resist layer.

4. The printed wiring board according to claim 1, wherein the metal layer has a portion formed on the portion of the conductive pattern such that the portion of the metal layer on the portion of the conductive pattern has a curved surface.

5. The printed wiring board according to claim 1, wherein the conductive pattern has a pad portion on which the bump structure is formed and a wiring portion extending from the pad portion, and the pad portion of the conductive pattern has substantially a rectangle shape.

6. The printed wiring board according to claim 5, wherein the pad portion of the conductive pattern has a plurality of corners having substantially an arc shape in a cross-section.

7. The printed wiring board according to claim 5, wherein the wiring portion of the conductive pattern has a width which is substantially equal to a width of the pad portion of the conductive pattern.

8. The printed wiring board according to claim 5, wherein the opening portion of the solder-resist layer has the center positioned in the center of the pad portion of the conductive pattern in an axis direction of the pad portion of the conductive pattern.

9. The printed wiring board according to claim 1, wherein the metal layer is formed of a single layer made of a metal selected from the group consisting of tin, gold, silver, palladium and platinum.

10. The printed wiring board according to claim 1, wherein the metal layer is formed of a single layer.

11. The printed wiring board according to claim 1, wherein the conductive pattern has an electroless plated film portion and an electrolytic plated film portion formed on the electroless plated film portion.

12. The printed wiring board according to claim 1, wherein the metal layer is formed of a plurality of metal layers.

13. The printed wiring board according to claim 1, wherein the conductive pattern has a pad portion on which the bump structure is formed and a wiring portion extending from the pad portion, the pad portion of the conductive pattern has substantially a rectangle shape, the wiring portion of the conductive pattern has a width which is substantially equal to a width of the pad portion of the conductive pattern, and the opening portion of the solder-resist layer has the center positioned in the center of the pad portion of the conductive pattern in an axis direction of the pad portion of the conductive pattern.

14. The printed wiring board according to claim 1, wherein the metal layer is formed of a plurality of metal layers comprising a nickel-plated layer and a gold-plated layer formed on the nickel-plated layer.

15. A method for manufacturing a printed wiring board, comprising:
forming a conductive pattern on an interlayer insulation layer;
forming a solder-resist layer on the interlayer insulation layer and the conductive pattern;
forming an opening portion in the solder-resist layer such that the opening portion of the solder-resist layer exposes a portion of the conductive pattern and a portion of the interlayer insulation layer around the portion of the conductive pattern;
forming a metal layer in the opening portion of the solder-resist layer such that the metal layer covers the portion of the conductive pattern and the portion of the interlayer insulation layer exposed through the opening portion of the solder-resist layer; and
forming a bump structure in the opening portion of the solder-resist layer such that the bump structure is formed on the metal layer in the opening portion of the solder-resist layer.

16. The method for manufacturing a printed wiring board according to claim 15, wherein the forming of the conductive pattern comprises applying a catalyst on the interlayer insulation layer, forming an electroless plated film on the interlayer insulation layer, forming a plating resist having a pattern on the electroless plated film, forming an electrolytic plated film on a portion of the electroless plated film exposed through the pattern of the plating resist, and removing the plating resist and a portion of the electroless plated film underneath the plating resist such that the conductive pattern comprising the electrolytic plated film and the portion of the electroless plated film underneath the electrolytic plated film is formed on the interlayer insulation layer.

17. The method for manufacturing a printed wiring board according to claim 15, further comprising roughening a surface of the portion of the interlayer insulation layer exposed through the opening portion of the solder-resist layer.

18. The method for manufacturing a printed wiring board according to claim 15, wherein the forming of the conductive pattern includes forming a pad portion on which the bump structure is formed and a wiring portion extending from the pad portion, the pad portion of the conductive pattern is formed in substantially a rectangle shape such that the wiring portion of the conductive pattern has a width which is substantially equal to a width of the pad portion of the conductive pattern.

19. The method for manufacturing a printed wiring board according to claim 16, further comprising roughening a surface of the portion of the interlayer insulation layer exposed through the opening portion of the solder-resist layer.

20. The method for manufacturing a printed wiring board according to claim 16, wherein the removing of the portion of the electroless plated film includes leaving the catalyst on the interlayer insulation layer.
